(19) United States
(12) Patent Application Publication
(10) Pub. No.: US 2023/0124769 A1
(43) Pub. Date: Apr. 20, 2023

(54) LIGHT-EMITTING STRUCTURES AND MANUFACTURING METHODS THEREOF

(71) Applicant: ENKRIS SEMICONDUCTOR, INC., Suzhou (CN)

(72) Inventor: Kai Cheng, Suzhou (CN)

(73) Assignee: ENKRIS SEMICONDUCTOR, INC., Suzhou (CN)

(21) Appl. No.: 17/968,066

(22) Filed: Oct. 18, 2022

(30) Foreign Application Priority Data
Oct. 20, 2021 (CN) 202111222881.8

(51) Int. Cl. H01L 33/44; H01L 33/00; H01L 33/32; H01L 33/42

(52) U.S. Cl. CPC H01L 33/44; H01L 33/007; H01L 33/32; H01L 33/42; H01L 2933/0025

(57) ABSTRACT

The present disclosure provides a light-emitting structure and a manufacturing method thereof. The light-emitting structure includes: a GaN-based LED structure and a nitrogen-containing passivation layer located on a sidewall of the GaN-based LED structure; wherein the GaN-based LED structure includes: a first semiconductor layer, a second semiconductor layer, and a light-emitting layer located between the first semiconductor layer and the second semiconductor layer, conductivity types of the first semiconductor layer and the second semiconductor layer are opposite.

### CROSS REFERENCE TO RELATED APPLICATIONS

This application claims priority to Chinese Patent Application No. 2021112228818 entitled “Light-emitting structures and manufacturing methods thereof” filed on 20^{th}, October, 2021, the entire content of which is incorporated herein by reference.

### TECHNICAL FIELD

The present disclosure relates to a technical field of semiconductors, and in particular, to light-emitting structures and manufacturing methods thereof.

### BACKGROUND

Group III nitrides are the third generation of new semiconductor materials after the first and the second generation semiconductor materials such as Si and GaAs. Among the group III nitrides, GaN has many advantages as a wide bandgap semiconductor material, such as high saturation drift velocity, high breakdown voltage, excellent carrier transport performance, and can form ternary alloys of AlGaN and InGaN and quaternary alloy of AlInGaN and the like and can be easily made into GaN-based PN junctions. In view of this, GaN-based materials and semiconductor devices have been extensively and deeply studied in recent years, and Metal-organic Chemical Vapor Deposition (MOCVD) technology has become increasingly mature for growing GaN-based materials. In the aspect of researching on semiconductor devices, the researches on optoelectronic devices such as light-emitting diode (LED) and laser diode (LD) and microelectronic devices such as GaN-based HEMT have made remarkable achievements and great progress.

With the gradual developing of the application of GaN-based materials in light-emitting devices, the demand for yield rate of terminal products in the industry has further increased. How to reduce leakage and prolong the service life of LED are the key research direction.

### SUMMARY

The purpose of the present disclosure is to provide light-emitting structures and manufacturing methods thereof.

In order to achieve the above object, a first aspect of the present disclosure provides a light-emitting structure, including: a GaN-based LED structure and a nitrogen-containing passivation layer located on a sidewall of the GaN-based LED structure; wherein the GaN-based LED structure includes:

a first semiconductor layer, a second semiconductor layer, and a light-emitting layer located between the first semiconductor layer and the second semiconductor layer, wherein conductivity types of the first semiconductor layer and the second semiconductor layer are opposite.

In some examples, a material of the nitrogen-containing passivation layer includes at least one of an AlN layer, a SiN layer, or a GaN layer.

In some examples, the nitrogen-containing passivation layer further covers a side of the first semiconductor layer away from the light-emitting layer, or covers a side of the second semiconductor layer away from the light-emitting layer.

In some examples, the light-emitting structure further includes:
a first electrode electrically connected to the first semiconductor layer; and
a second electrode electrically connected to the second semiconductor layer.

In some examples, the first electrode and the second electrode are located on a same side or on both sides of the GaN-based LED structure.

In some examples, a first patterned mask layer located between the nitrogen-containing passivation layer and the GaN-based LED structure.

In some examples, the first patterned mask layer is an insulating material.

In some examples, the first patterned mask layer and the nitrogen-containing passivation layer include an opening, and the opening expose a partial region of an upper surface of the second semiconductor layer; an region of the second semiconductor layer corresponding to the opening is an active area, and an region of the second semiconductor layer covered by the first patterned mask layer is an inactive region.

In some embodiments, the light-emitting structure further includes: first electrode electrically connected to the first semiconductor layer; and a second electrode formed in the opening and on the nitrogen-containing passivation layer, the second electrode is electrically connected to the second semiconductor layer, and a material of the second electrode includes indium tin oxide.

In some embodiments, the GaN-based LED structure is in stair shape, and the second semiconductor layer 11b and the light-emitting layer 11c expose a partial region of the first semiconductor layer 11a.

A second aspect of the present disclosure provides manufacturing methods for a light-emitting structure, including:
providing a substrate, on which a first semiconductor material layer, a light-emitting material layer and a second semiconductor material layer are sequentially formed, a conductivity type of dopant ions in the second semiconductor material layer is opposite to a conductivity type of dopant ions in the first semiconductor material layer;
forming a first patterned mask layer on the second semiconductor material layer, and using the first patterned mask layer as a mask to dry etch the second semiconductor material layer, the light-emitting material layer, and the first semiconductor material layer, correspondingly to form GaN-based LED structures, each of the GaN-based LED structures including: a first semiconductor layer, a second semiconductor layer, and a light-emitting layer between the first semiconductor layer and the second semiconductor layer;
adding NH₃ and one or more precursors, to epitaxially grow a nitrogen-containing passivation layer on a sidewall of the GaN-based LED structure.

In some examples, the one or more precursors are at least one of TMAl, Si₂H₆ or TMGa, and the corresponding epitaxial grown nitrogen-containing passivation layer is at least one of AlN layer, SiN layer or GaN layer.

In some examples, after a step of forming GaN-based LED structures by dry etching, and before a step of epitaxially growing a nitrogen-containing passivation layer on the sidewall, the manufacturing method further includes: performing an annealing process, and in the annealing process, passing an NH₃ to repair the sidewall of the GaN-based LED structure;

the epitaxial growth of the nitrogen-containing passivation layer is in-situ epitaxial growth.

In some examples, the first patterned mask layer is an insulating material, and when epitaxially growing the nitrogen-containing passivation layer on the sidewall, further epitaxially growing the nitrogen-containing passivation layer on the first patterned mask layer.

In some examples, the dopant ions in the second semiconductor material layer are P-type dopant ions; the manufacturing method for the light-emitting structure further includes: forming an opening in the first patterned mask layer and the nitrogen-containing passivation layer to expose a partial region of an upper surface of the second semiconductor layer; activating the exposed second semiconductor layer by using the first patterned mask layer and the nitrogen-containing passivation layer as a mask to form an active region, a region of the second semiconductor layer covered with the first patterned mask layer and the nitrogen-containing passivation layer is an inactive region.

In some examples, after the step of forming GaN-based LED structures by dry etching, and before the step of epitaxially growing a nitrogen-containing passivation layer on the sidewall, the manufacturing method further includes: removing the first patterned mask layer, to expose the second semiconductor layer;

when epitaxially growing the nitrogen-containing passivation layer on the sidewall, further epitaxially growing the nitrogen-containing passivation layer on the second semiconductor layer.

In some examples, the dopant ions in the second semiconductor material layer are P-type dopant ions; the manufacturing method for the light-emitting structure further includes: forming an opening in the nitrogen-containing passivation layer to expose a partial region of an upper surface of the second semiconductor layer; activating the exposed second semiconductor layer by using the nitrogen-containing passivation layer as a mask to form an active region, and a region of the second semiconductor layer covered with the nitrogen-containing passivation layer is an inactive region.

In some examples, after the step of epitaxially growing the nitrogen-containing passivation layer on the sidewall, the manufacturing method further includes:
removing the first patterned mask layer to expose the second semiconductor layer;
adding NH₃ and the one or more precursors, to epitaxially grow the nitrogen-containing passivation layer on the second semiconductor layer.

In some examples, after the step of removing the first patterned mask layer to expose the second semiconductor layer, and before passing in the NH₃ and the one or more precursors to epitaxially grow the nitrogen-containing passivation layer on the second semiconductor layer, the manufacturing method further includes: implanting H atoms into an edge region on an upper surface of the second semiconductor layer.

### BRIEF DESCRIPTION OF DRAWINGS

FIG. 1 is a flowchart of a manufacturing method of a light-emitting structure according to a first embodiment of the present disclosure.

FIG. 2 and FIG. 3 are schematic diagrams of intermediate structures corresponding to the process in FIG. 1.

FIG. 4 is a schematic cross-sectional structure diagram of the light-emitting structure according to the first embodiment of the present disclosure.

FIG. 5 is a schematic cross-sectional structural diagram of a light-emitting structure according to a second embodiment of the present disclosure.

FIG. 6 is a schematic cross-sectional structure diagram of a light-emitting structure according to a third embodiment of the present disclosure.

FIG. 7 is a schematic cross-sectional structural diagram of a light-emitting structure according to a fourth embodiment of the present disclosure.

FIG. 8 is a schematic cross-sectional structural diagram of a light-emitting structure according to a fifth embodiment of the present disclosure.

### DETAILED DESCRIPTION

In order to make the above-mentioned objects, features and advantages of the present disclosure more obvious and understandable, embodiments of the present disclosure will be described in detail below with reference to the accompanying drawings.

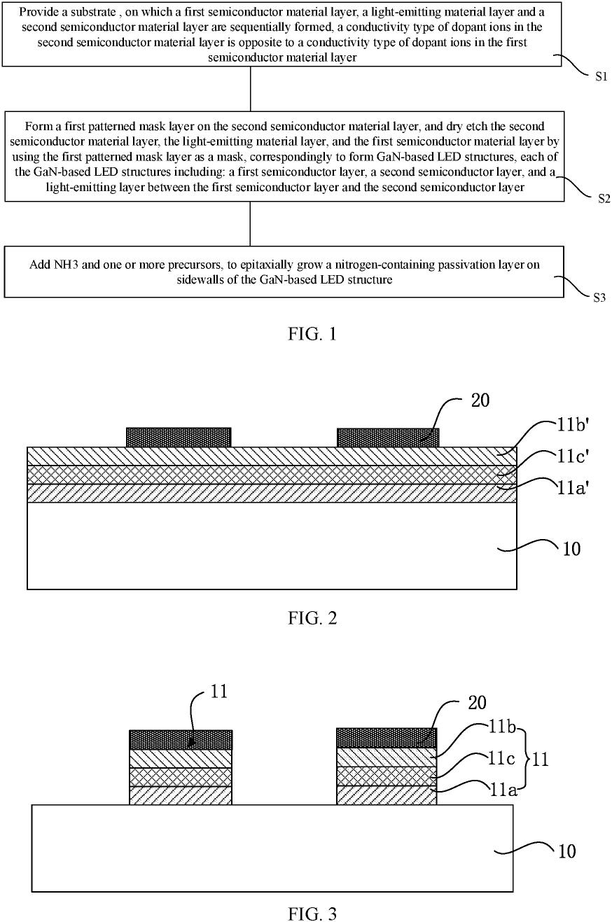

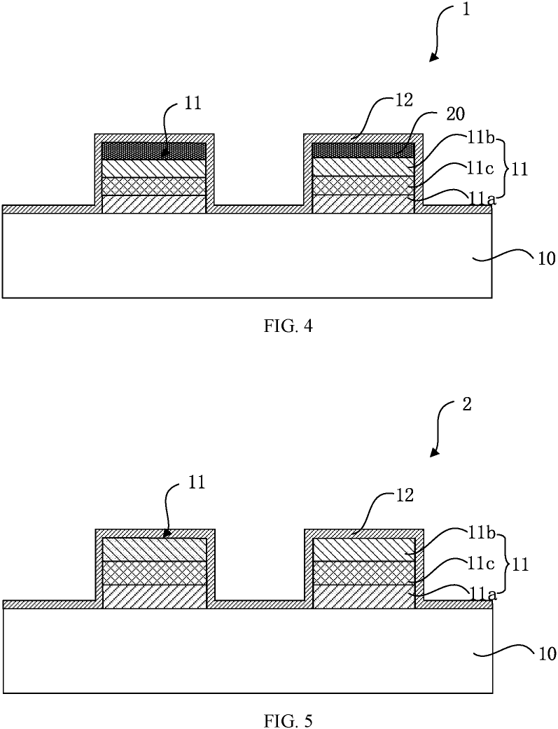

FIG. 1 is a flowchart of a manufacturing method of a light-emitting structure according to a first embodiment of the present disclosure; FIG. 2 and FIG. 3 are schematic diagrams of intermediate structures corresponding to the process in FIG. 1. FIG. 4 is a schematic cross-sectional structure diagram of the light-emitting structure according to the first embodiment of the present disclosure.

First, referring to step S1 in FIG. 1 and as shown in FIG. 2, a substrate 10 is provided, and a first semiconductor material layer 11a′, a light-emitting material layer 11c′ and a second semiconductor material layer 11b′ are formed on the substrate 10 in sequence. A conductivity type of dopant ions in the second semiconductor material layer 11b′ is opposite to a conductivity type of dopant ions in the first semiconductor material layer 11a′.

The substrate 10 may include sapphire, silicon carbide, silicon, silicon-on-insulator (SOI), lithium niobate, diamond or other materials.

In this embodiment, the conductivity type of the dopant ions in the first semiconductor material layer 11a′ may be N-type, and the conductivity type of the dopant ions in the second semiconductor material layer 11b′ is P-type. The semiconductor material layer with N-type dopant ions (hereinafter may also be referred to as the N-type semiconductor layer) is close to the substrate 10, and the semiconductor material layer with the P-type dopant ions (hereinafter may also be referred to as the P-type semiconductor layer) is far away from the substrate 10. In other embodiments, the P-type semiconductor layer may be close to the substrate 10, and the N-type semiconductor layer may be away from the substrate 10.

In this embodiment, a nucleation layer and a buffer layer (not shown in the figures) may be formed between the N-type semiconductor layer and the substrate 10. The material of the nucleation layer may be, for example, AlN, AlGaN or the like. The material of the buffer layer may include at least one of AlN, GaN, AlGaN or AlInGaN. The nucleation layer can alleviate the problems of lattice mismatch and thermal mismatch between the epitaxially grown semiconductor layer (such as the N-type semiconductor layer) and the substrate 10, and the buffer layer can reduce the dislocation density and defect density of the epitaxially grown semiconductor layer to improve crystal quality.

Materials of the P-type semiconductor layer and the N-type semiconductor layer may be group III nitride materials, such as at least one of GaN, AlGaN or AlInGaN. The P-type dopant ions can be at least one kind of Mg ions, Zn ions, Ca ions, Sr ions or Ba ions, and the N-type dopant ions can be at least one kind of Si ions, Ge ions, Sn ions, Se ions or Te ions.

A forming process of the P-type semiconductor layer or the N-type semiconductor layer may include: atomic layer deposition (ALD), chemical vapor deposition (CVD), molecular Beam Epitaxy (MBE), Plasma Enhanced Chemical Vapor Deposition (PECVD), Low Pressure Chemical Vapor Deposition (LPCVD), Metal Organic Compounds Chemical vapor deposition (MOCVD), or a combination thereof, where P-type ions and N-type ions can be doped in-situ, or doped by ion implantation after epitaxial growth of group III nitride materials.

Light-emitting material layer 11c′ may include at least one of a single quantum well structure, a multiple quantum well (MQW) structure, a quantum wire structure, or a quantum dot structure. The light-emitting material layer 11c′ may include a potential well layer and a barrier layer. The materials of the potential well layer and the barrier layer may be group III nitride materials.

In this embodiment, the P-doped ions in the P-type semiconductor layer are activated by an annealing process in this step S1.

Next, referring to step S2 in FIG. 1 and as shown in FIG. 2 and FIG. 3, a first patterned mask layer 20 is formed on the second semiconductor material layer 11b′. Using the first patterned mask layer 20 as a mask, the second semiconductor material layer 11b′, the luminescent material layer 11c′ and the first semiconductor material layer 11a′ are etched by dry etching to form a plurality of GaN-based LED structures 11, each GaN-based LED structure 11 includes: a first semiconductor layer 11a, a light-emitting layer 11c and a second semiconductor layer 11b from bottom to top.

A material of the first patterned mask layer 20 can be silicon dioxide, silicon nitride or the like, and the first patterned mask layer 20 may be formed by a physical vapor deposition method or a chemical vapor deposition method. The patterning of the mask layer 20 may be performed by dry etching or wet etching.

In the dry etching process, defects will be formed on the sidewalls of the first semiconductor layer 11a, the light-emitting layer 11c and the second semiconductor layer 11b, and the defects will lead to the generation of non-radiative recombination, reducing the luminous efficiency.

A GaN-based LED structure 11 is a multi-layer structure formed by the first semiconductor layer 11a, the light-emitting layer 11c, and the second semiconductor layer 11b. In this embodiment, there may be a plurality of GaN-based LED structures 11 on the substrate 10.

Next, referring to step S3 in FIG. 1 and as shown in FIG. 4, NH₃ and one or more precursors are introduced, and a nitrogen-containing passivation layer 12 is epitaxially grown on sidewalls of the GaN-based LED structures 11.

In some examples, the one or more precursors may include at least one of TMAl (trimethylaluminum), Si₂H₆ (disilane) or TMGa (trimethylgallium), and correspondingly, the nitrogen-containing passivation layer 12 epitaxially grown may be at least one of AlN layer, SiN layer or GaN layer.

The nitrogen-containing passivation layer 12 epitaxially grown on the sidewalls of the GaN-based LED structure 11 can passivate the sidewalls of the first semiconductor layer 11a and the second semiconductor layer 11b to reduce non-radiative recombination. In addition, the first semiconductor layer 11a and the second semiconductor layer 11b on both sides of the light-emitting layer 11c can also be prevented from leakage of electricity, or even short-circuiting.

In this embodiment, before epitaxial growth of the nitrogen-containing passivation layer 12, an annealing process may be performed, and during the annealing process, NH₃ is introduced to repair the sidewalls of the GaN-based LED structure 11, and NH₃ decomposes into N atom and H atom, which can neutralize the dangling bonds in the sidewalls of the GaN-based LED structure 11 to prevent the dangling bonds from capturing electrons during the light-emitting process, thereby improving the light-emitting efficiency.

In addition, the annealing process and the epitaxial growth of the nitrogen-containing passivation layer 12 can be performed in the same reaction chamber, so the epitaxial growth of the nitrogen-containing passivation layer 12 is in-situ epitaxial growth.

In this embodiment, the first patterned mask layer 20 is made of an insulating material, and the nitrogen-containing passivation layer 12 is also epitaxially grown on the first patterned mask layer 20 while the nitrogen-containing passivation layer 12 is epitaxially grown on the sidewalls of the GaN-based LED structures 11. In other words, the first patterned mask layer 20 remains in the light-emitting structure 1.

Referring to FIG. 4, the light-emitting structure 1 of this embodiment includes:
a substrate 10;
GaN-based LED structures 11 located on the substrate 10, the GaN-based LED structures 11 each includes from bottom to top: a first semiconductor layer 11a, a light-emitting layer 11c and a second semiconductor layer 11b. The conductivity types of the first semiconductor layer 11a and the second semiconductor layer 11b is opposite;
a first patterned mask layer 20 on the second semiconductor layer 11b; and
a nitrogen-containing passivation layer 12 located on sidewalls of the GaN-based LED structures 11 and the first patterned mask layer 20.

In this embodiment, the first semiconductor layer 11a may be an N-type semiconductor material layer, and the second semiconductor layer 11b may be a P-type semiconductor material layer. In other embodiments, the P-type semiconductor layer may be close to the substrate 10, and the N-type semiconductor layer may be far away from the substrate 10.

The nitrogen-containing passivation layer 12 is epitaxially grown on the sidewalls of the GaN-based LED structures 11, which can improve the dynamic characteristics of the LED structure 11 and prolong the service life of the LED structure 11.

The light-emitting structure 1 of the first embodiment can be produced and sold as a semi-finished product.

FIG. 5 is a schematic cross-sectional structural diagram of a light-emitting structure according to a second embodiment of the present disclosure. Referring to FIG. 5, the light-emitting structure 2 of the second embodiment differs from the light-emitting structure 1 of the first embodiment only in that: the first patterned mask layer 20 is omitted, and the nitrogen-containing passivation layer 12 also covers a side of the second semiconductor layer 11b away from the light-emitting layer 11c.

In addition to the above differences, other structures of the light-emitting structure 2 of the second embodiment may refer to the corresponding structures of the light-emitting structure 1 of the first embodiment.

The light-emitting structure 2 of the second embodiment can be produced and sold as a semi-finished product.

In an example, the difference between the manufacturing method of the light-emitting structure 2 of the second embodiment and the manufacturing method of the light-emitting structure 1 of the first embodiment is only that: the first patterned mask layer 20 is removed to expose the second semiconductor layer 11b between step S2 and step S3; in step S3, while the nitrogen-containing passivation layer 12 is epitaxially grown on the sidewalls of the GaN-based LED structures 11, the nitrogen-containing passivation layer 12 is also epitaxially grown on the second semiconductor layer 11b.

In another example, the difference between the manufacturing method of the light-emitting structure 2 of the second embodiment and the manufacturing method of the light-emitting structure 1 of the first embodiment is only that: after step S3, the first patterned mask layer 20 is removed, to expose the second semiconductor layer 11b; NH₃ and one or more precursors are added, and a nitrogen-containing passivation layer 12 is epitaxially grown on the second semiconductor layer 11b. In this example, after the first patterned mask layer 20 is removed to expose the second semiconductor layer 11b, before NH₃ and one or more precursors are added, and the nitrogen-containing passivation layer 12 is epitaxially grown on the second semiconductor layer 11b, the manufacturing method may further include: a patterned mask layer is formed on the exposed second semiconductor layer 11b to expose an edge region of the upper surface of the second semiconductor layer 11b; and then H atoms are implanted into the edge region of the upper surface of the second semiconductor layer 11b by using the patterned mask layer as a mask, to reduce non-radiative recombination at the edge of the second semiconductor layer 11b. A gas source of H atoms can be H₂, SiH₄ or NH₃.

The manufacturing method provided by the second embodiment is suitable for the case where the nitrogen-containing passivation layer 12 cannot be epitaxially grown on the first patterned mask layer 20.

The nitrogen-containing passivation layer 12 on the second semiconductor layer 11b can passivate the upper surface of the second semiconductor layer 11b to reduce non-radiative recombination.

In addition to the above differences, other steps of the manufacturing method for the light-emitting structure 2 of the second embodiment may refer to the corresponding steps of the manufacturing method for the light-emitting structure 1 of the first embodiment.

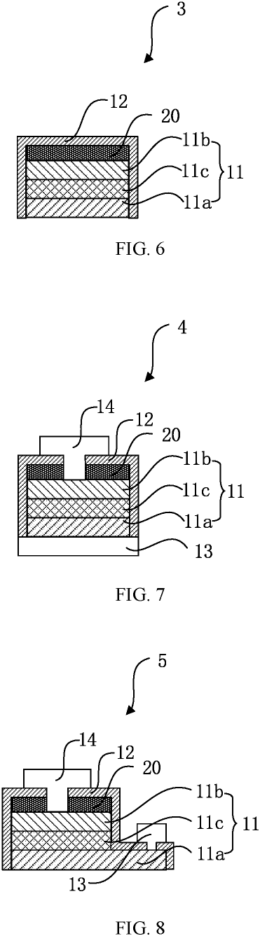

FIG. 6 is a schematic cross-sectional structural diagram of a light-emitting structure according to a third embodiment of the present disclosure. Referring to FIG. 6, the light-emitting structure 3 of the third embodiment differs from the light-emitting structures 1 and 2 of the first and second embodiments only in that: the substrate 10 is omitted.

In addition to the above differences, other structures of the light-emitting structure 3 of the third embodiment may refer to the corresponding structures of the light-emitting structures 1 and 2 of the first and second embodiments.

The light-emitting structure 3 of the third embodiment can be produced and sold as a semi-finished product.

Correspondingly, the difference between the manufacturing method of the light-emitting structure 3 in the third embodiment and the manufacturing method of the light-emitting structures 1 and 2 in the first and second embodiments is only that: the substrate 10 is removed after step S3.

The substrate 10 can be removed by using a laser lift-off method.

In addition to the above differences, other steps of the manufacturing method of the light-emitting structure 3 of the third embodiment may refer to the corresponding steps of the manufacturing methods of the light-emitting structures 1 and 2 of the first and second embodiments.

FIG. 7 is a schematic cross-sectional structure diagram of a light-emitting structure according to a fourth embodiment of the present disclosure. Referring to FIG. 7, the light-emitting structure 4 of the fourth embodiment differs from the light-emitting structure 3 of the third embodiment only in that: the light-emitting structure 4 further includes:
a first electrode 13, electrically connected to the first semiconductor layer 11a; and
a second electrode 14; electrically connected to the second semiconductor layer 11b;
where the first electrode 13 and the second electrode 14 are located on both sides of the GaN-based LED structure 11 respectively.

The materials of the first electrode 13 and the second electrode 14 may be metals, such as conductive materials such as Ti/Al/Ni/Au, Ni/Au, and the like.

In this embodiment, since the second electrode 14 is formed on the nitrogen-containing passivation layer 12, the second electrode 14 correspondingly penetrates through the nitrogen-containing passivation layer 12 and the first patterned mask layer 20, and an ohmic contact is formed between the second electrode 14 and the second semiconductor layer 11b.

In addition to the above differences, other structures of the light-emitting structure 4 of the fourth embodiment may refer to the corresponding structures of the light-emitting structure 3 of the third embodiment.

In an example, the difference between the manufacturing method of the light-emitting structure 4 of the fourth embodiment and the manufacturing method of the light-emitting structure 3 of the third embodiment is only that: after the substrate 10 is removed, a first electrode 13 electrically connected to the first semiconductor layer 11a is formed on a side of the first semiconductor layer 11a far away from the light-emitting layer 11c; and a second electrode 14 electrically connected to the second semiconductor layer 11b is formed on a side of the second semiconductor layer 11b away from the light-emitting layer 11c.

The first electrode 13 and the second electrode 14 may be formed by physical vapor deposition or chemical vapor deposition. In other embodiments, the first electrode 13 may also be a metal plate, which is connected with the light-emitting structure 4 through a bonding process.

In another example, the difference between the manufacturing method of the light-emitting structure 4 of the fourth embodiment and the manufacturing method of the light-emitting structure 3 of the third embodiment is only that: a) for the scheme of the light-emitting structure 1 of the first embodiment where the first patterned layer is retained, in step S1, the dopant ions in the second semiconductor material layer 11b′ are not activated at first, that is, the P-type dopant ions in the second semiconductor material layer 11b′ have not been annealed, so the P-type dopant ions are not activated and the second semiconductor material layer does not exhibit P-type material properties; after step S3, an opening is formed in the first patterned mask layer 20 and the nitrogen-containing passivation layer 12 to expose a part of the upper surface of the second semiconductor layer 11b; then an annealing process is performed to activate the exposed second semiconductor layer 11b to form an active region. In the annealing process, the opening can provide an escape path for the released H atoms to activate the dopant ions, which is because: when using Metal-organic Chemical Vapor Deposition (MOCVD) technology to grow P-type GaN-based materials, there are a large number of H atoms in the MOCVD growth environment. If these H atoms are not removed, the acceptor dopant in the GaN-based material, such as Mg, will be passivated by the large number of H atoms without generating holes, and thus the second semiconductor layer 11b cannot show P-type material properties.

The region of the second semiconductor layer 11b covered by the first patterned mask layer 20 and the nitrogen-containing passivation layer 12 is an inactive region.

Or b) for the scheme of the light-emitting structure 2 of the second embodiment where the first patterned mask layer 20 is omitted, the dopant ions in the second semiconductor material layer 11b′ are not activated first in step S1, that is, the P-type dopant ions are not annealed, so the P-type dopant ions are not activated and the second semiconductor material layer 11b′ does not show P-type material properties; after step S3, an opening is formed in the nitrogen-containing passivation layer 12 to expose a part of the upper surface of the second semiconductor layer 11b; then an annealing process is performed, and the exposed second semiconductor layer 11b is activated to form an active region.

A region of the second semiconductor layer 11b covered by the nitrogen-containing passivation layer 12 is an inactive region.

Or c) for the scheme with the first patterned mask layer 20 in the light-emitting structure 1 of the first embodiment, or for the scheme without the first patterned mask layer 20 in the light-emitting structure 2 of the second embodiment, in step S1, the dopant ions in the second semiconductor material layer 11b′ are not activated first, that is, the P-type dopant ions in the second semiconductor material layer 11b′ have not been annealed, so P-type dopant ions are not activated and the second semiconductor material layer does not exhibit P-type material properties; after step S3, in the first embodiment, an opening is formed in the first patterned mask layer 20 and the nitrogen-containing passivation layer 12 (or in the nitrogen-containing passivation layer 12 in the second embodiment), and a second electrode 14 is formed in the opening and on the nitrogen-containing passivation layer 12, the material of the second electrode 14 is ITO (indium tin oxide). In the process of forming the second electrode 14, the second semiconductor layer 11b in contact with the bottom wall of the second electrode 14 is activated, which is because: ITO is an oxide, and thus H atoms in the second semiconductor layer 11b can be precipitated to avoid passivation for dopant ions.

In the schemes a), b) and c), the second semiconductor layer 11b is selectively activated, that is, the edge region is not activated. Compared with the scheme in which the second semiconductor layer 11b is fully activated, the advantages of the scheme in which the edge region is not activated are: on the one hand, damage to the sidewall of the second semiconductor layer 11b can be reduced, and on the other hand, the non-radiative recombination of the edge of the second semiconductor layer 11b can be reduced.

In addition to the above differences, for other steps in the manufacturing method for the light-emitting structure 4 in the fourth embodiment may refer to the corresponding steps in the manufacturing method for the light-emitting structure 3 in the third embodiment.

FIG. 8 is a schematic cross-sectional structural diagram of a light-emitting structure according to a fifth embodiment of the present disclosure. Referring to FIG. 8, the light-emitting structure 5 of the fifth embodiment differs from the light-emitting structures 1, 2, and 3 of the first, second, and third embodiments only in that: the light-emitting structure 5 further includes:
a first electrode 13, electrically connected to the first semiconductor layer 11a; and
a second electrode 14, electrically connected to the second semiconductor layer 11b;
where the first electrode 13 and the second electrode 14 are located on the same side of the GaN-based LED structure 11.

The materials of the first electrode 13 and the second electrode 14 may be metals, such as conductive materials such as Ti/Al/Ni/Au, Ni/Au, and the like.

In this embodiment, in step S2, the formed GaN-based LED structure 11 is in stair shape, and the second semiconductor layer 11b and the light-emitting layer 11c expose a part of the first semiconductor layer 11a.

In this embodiment, since the first electrode 13 and the second electrode 14 are formed on the nitrogen-containing passivation layer 12, the first electrode 13 penetrates through the nitrogen-containing passivation layer 12 and forms an ohmic contact with the first semiconductor layer 11a; the second electrode 14 correspondingly penetrates through the nitrogen-containing passivation layer 12 and the first patterned mask layer 20 to form an ohmic contact with the second semiconductor layer 11b.

In addition to the above differences, other structures of the light-emitting structure 5 of the fifth embodiment may refer to the corresponding structures of the light-emitting structures 1, 2, and 3 of the first, second, and third embodiments.

Correspondingly, the difference between the manufacturing method for the light-emitting structure 5 in the fifth embodiment and the manufacturing method for the light-emitting structures 1, 2, and 3 in the first, second, and third embodiments is only that: in step S2, a second patterned mask layer is formed on the second semiconductor material layer 11b′ firstly, and the first semiconductor material layer 11a′, the light-emitting material layer 11c′, and the second semiconductor material layer 11b′ are etched through the second patterned mask layer to form a plurality of discrete multi-layer structures of the first semiconductor material layer 11a′, the light-emitting material layer 11c′, and the second semiconductor material layer 11b′, and the second patterned mask layer is removed; then a first patterned mask layer 20 is formed on the second semiconductor material layer 11b′ of the each of the multi-layer structures, the second semiconductor material layer 11b′ and the light-emitting material layer 11c′ are etched through the first patterned mask layer 20 to expose a partial region of the first semiconductor material layer 11a′; in step S3, the nitrogen-containing passivation layer 12 covers the upper surface of the first patterned mask layer 20, the side surfaces of the first patterned mask layer 20, the second semiconductor material layer 11b′ and the light-emitting material layer 11c′, and the exposed upper surface of the first semiconductor layer 11a′ and the side surfaces of the first semiconductor material layer 11a′; then, a first electrode 13 electrically connected to the first semiconductor layer 11a is formed on the side of the first semiconductor layer 11a close to the light-emitting layer 11c; and a second electrode 14 electrically connected to the second semiconductor layer 11b is formed on the side of the second semiconductor layer 11b away from the light-emitting layer 11c.

The first electrode 13 and the second electrode 14 may be formed by physical vapor deposition or chemical vapor deposition.

Scheme a), scheme b) and scheme c) of the above-mentioned fourth embodiment can also be combined into the fifth embodiment.

In addition to the above differences, other steps of the manufacturing method for the light-emitting structure 5 of the fifth embodiment may refer to the corresponding steps of the manufacturing methods for the light-emitting structures 1, 2, and 3 of the first, second, and third embodiments.

Although the present disclosure is disclosed above, the present disclosure is not limited thereto. Any person skilled in the art can make various changes and modifications without departing from the spirit and scope of the present disclosure. Therefore, the protection scope of the present disclosure should be based on the scope defined by the claims.

What is claimed is:

1. A light-emitting structure, comprising: a GaN-based LED structure and a nitrogen-containing passivation layer located on a sidewall of the GaN-based LED structure; wherein the GaN-based LED structure comprises:
a first semiconductor layer, a second semiconductor layer, and a light-emitting layer located between the first semiconductor layer and the second semiconductor layer, wherein conductivity types of the first semiconductor layer and the second semiconductor layer are opposite.

2. The light-emitting structure according to claim 1, wherein a material of the nitrogen-containing passivation layer comprises at least one of an AlN layer, a SiN layer, or a GaN layer.

3. The light-emitting structure according to claim 1, wherein the nitrogen-containing passivation layer further covers a side of the first semiconductor layer away from the light-emitting layer, or covers a side of the second semiconductor layer away from the light-emitting layer.

4. The light-emitting structure according to claim 1, further comprising:
a first electrode electrically connected to the first semiconductor layer; and
a second electrode electrically connected to the second semiconductor layer.

5. The light-emitting structure according to claim 4, wherein the first electrode and the second electrode are located on a same side or located separately on both sides of the GaN-based LED structure.

6. The light-emitting structure according to claim 1, further comprising:
a first patterned mask layer located between the nitrogen-containing passivation layer and the GaN-based LED structure.

7. The light-emitting structure according to claim 6, wherein the first patterned mask layer is made of an insulating material.

8. The light-emitting structure according to claim 6, wherein the first patterned mask layer and the nitrogen-containing passivation layer comprise an opening, and the opening exposes a partial region of an upper surface of the second semiconductor layer; a region of the second semiconductor layer corresponding to the opening is an active region, and a region of the second semiconductor layer covered by the first patterned mask layer is an inactive region.

9. The light-emitting structure according to claim 8, further comprising:
a first electrode electrically connected to the first semiconductor layer; and
a second electrode formed in the opening and on the nitrogen-containing passivation layer, the second electrode is electrically connected to the second semiconductor layer, and a material of the second electrode includes indium tin oxide.

10. The light-emitting structure according to claim 1, wherein the GaN-based LED structure is in stair shape, and the second semiconductor layer 11b and the light-emitting layer 11c expose a partial region of the first semiconductor layer 11a.

11. A manufacturing method for a light-emitting structure, comprising:
providing a substrate;
sequentially forming a first semiconductor material layer, a light-emitting material layer and a second semiconductor material layer on the substrate, wherein a conductivity type of dopant ions in the second semiconductor material layer is opposite to a conductivity type of dopant ions in the first semiconductor material layer;
forming a first patterned mask layer on the second semiconductor material layer;
dry etching the second semiconductor material layer, the light-emitting material layer, and the first semiconductor material layer by using the first patterned mask layer as a mask, correspondingly to form GaN-based LED structures, each of the GaN-based LED structures comprising: a first semiconductor layer, a second semiconductor layer, and a light-emitting layer between the first semiconductor layer and the second semiconductor layer;
adding NH3 and one or more precursors to epitaxially grow a nitrogen-containing passivation layer on sidewalls of the GaN-based LED structures.

12. The manufacturing method according to of claim 11, wherein the one or more precursors are at least one of TMAl, Si₂H₆ or TMGa, and the corresponding epitaxial grown nitrogen-containing passivation layer is at least one of AlN layer, SiN layer or GaN layer.

13. The manufacturing method according to claim 11, wherein after forming the GaN-based LED structures, and before epitaxially growing the nitrogen-containing passivation layer on the sidewall, the manufacturing method further comprises:
performing an annealing process, wherein in the annealing process, NH₃ is added to repair the sidewall of the GaN-based LED structure, and the epitaxial growth of the nitrogen-containing passivation layer is in-situ epitaxial growth.

14. The manufacturing method according to claim 11, wherein the first patterned mask layer is made of an insulating material, and the method further comprises:
while epitaxially growing the nitrogen-containing passivation layer on the sidewall, epitaxially growing the nitrogen-containing passivation layer on the first patterned mask layer.

15. The manufacturing method according to claim 14, wherein the dopant ions in the second semiconductor material layer are P-type dopant ions; the method further comprises:
forming an opening in the first patterned mask layer and the nitrogen-containing passivation layer to expose a partial region of an upper surface of the second semiconductor layer;
activating the exposed second semiconductor layer by using the first patterned mask layer and the nitrogen-containing passivation layer as a mask to form an active region, wherein a region of the second semiconductor layer covered with the first patterned mask layer and the nitrogen-containing passivation layer is an inactive region.

16. The manufacturing method according to claim 11, wherein after forming the GaN-based LED structures, and before epitaxially growing the nitrogen-containing passivation layer on the sidewall, the method further comprises:
removing the first patterned mask layer to expose the second semiconductor layer;
while epitaxially growing the nitrogen-containing passivation layer on the sidewall, epitaxially growing the nitrogen-containing passivation layer on the second semiconductor layer.

17. The manufacturing method according to claim 16, wherein the dopant ions in the second semiconductor material layer are P-type dopant ions; the method further comprises:
forming an opening in the nitrogen-containing passivation layer to expose a partial region of an upper surface of the second semiconductor layer;
activating the exposed second semiconductor layer by using the nitrogen-containing passivation layer as a mask to form an active region, wherein a region of the second semiconductor layer covered with the nitrogen-containing passivation layer is an inactive region.

18. The manufacturing method according to claim 11, wherein after epitaxially growing the nitrogen-containing passivation layer on the sidewall, the method further comprises:
removing the first patterned mask layer to expose the second semiconductor layer;
adding NH₃ and the one or more precursors to epitaxially grow the nitrogen-containing passivation layer on the second semiconductor layer.

19. The manufacturing method according to claim 18, wherein after removing the first patterned mask layer to expose the second semiconductor layer, and before adding NH₃ and the one or more precursors to epitaxially grow the nitrogen-containing passivation layer on the second semiconductor layer, the method further comprises:
implanting H atoms into an edge region on an upper surface of the second semiconductor layer.
